(19) United States
(12) Patent Application Publication
(10) Pub. No.: US 2026/0206644 A1
(43) Pub. Date: Jul. 16, 2026

(54) PACKAGING CONDUCTION STRUCTURE, PACKAGE-ON-PACKAGE STRUCTURE, AND METHOD OF FORMING PACKAGING CONDUCTION STRUCTURE

(71) Applicant: WISTRON NEWEB CORPORATION, HSINCHU (TW)

(72) Inventors: SHEN-YU YANG, HSINCHU (TW); CHAO-CHIEH CHAN, HSINCHU (TW)

(21) Appl. No.: 19/077,155

(22) Filed: Mar. 12, 2025

(30) Foreign Application Priority Data
Jan. 13, 2025 (TW) 114101229

(51) Int. Cl. H01L 25/07; H01L 21/56; H01L 23/00; H01L 23/31; H01L 23/498; H01L 25/00

(52) U.S. Cl. CPC H10W 90/00; H10W 74/016; H10W 74/121; H10W 90/701; H10W 72/01261; H10W 72/234; H10W 72/252; H10W 72/255; H10W 90/20; H10W 90/724

(57) ABSTRACT

A packaging conduction structure includes a first packaging unit, a second packaging unit, and a conduction structure. The first packaging unit includes a first contact; the second packaging unit includes a second contact; and the conduction structure includes a first metal portion and a second metal portion, the first metal portion and the second metal portion are different metals, the second metal portion surrounds an entirety of the first metal portion, and the second metal portion is connected between the first contact and the second contact, wherein the first metal portion has a flat surface.

### CROSS-REFERENCE TO RELATED PATENT APPLICATION

This application claims the benefit of priority to Taiwan Patent Application No. 114101229, filed on Jan. 13, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a packaging technology, particularly to a packaging conduction structure, a package-on-package (POP) structure, and a method of forming a packaging conduction structure.

### BACKGROUND OF THE DISCLOSURE

Package-on-package (POP) technology generally refers to a circuit packaging technology that can stack multiple components together to form a high-density circuit structure, thereby reducing the overall structure size and the footprint on the circuit board. In addition, since various functional components can be incorporated into the POP structure, the POP structure can provide multiple functions. However, the stacking of components may lead to issues such as structural collapse, displacement, etc., and particularly the conduction structure between electrical contacts of components tends to be unstable. Therefore, the stability of the electrical contacts and the conduction structures in the vertical direction is particularly important. Conventional POP structures often use solder balls as the conduction structure between electrical contacts, but the solder balls tend to shrink significantly after going through a reflow process, resulting in unstable solder joint structures. Some POP structures also use copper pillars as the conduction structure, but the processing and equipment costs of using copper pillars are relatively high and are not cost-effective.

Therefore, there is a need for a packaging conduction structure that can solve the aforementioned issues.

### SUMMARY OF THE DISCLOSURE

The present disclosure provides a packaging conduction structure, a package-on-package (POP) structure, and a method of forming a packaging conduction structure, which can stabilize a packaging structure under cost-effective conditions. Applying the techniques of the present disclosure to POP structures can reduce POP structure size and footprint using high-density circuit structures, and can also ensure electrical conduction between electrical contacts with a stable conduction structure, avoiding issues such as structural collapse and displacement.

In some embodiments, a packaging conduction structure is provided, and includes: a first packaging unit including a first contact; a second packaging unit including a second contact; and a conduction structure including a first metal portion and a second metal portion, the first metal portion and the second metal portion being different metals, the second metal portion surrounding an entirety of the first metal portion, and the second metal portion being connected between the first contact and the second contact; wherein the first metal portion has a flat surface.

In some embodiments, a package-on-package (POP) structure is provided and includes: a first packaging unit including a first substrate and a first contact disposed on the first substrate; a second packaging unit including a second contact; and a plurality of conduction structures, each including a first metal portion and a second metal portion, the first metal portion and the second metal portion being different metals, the second metal portion surrounding an entirety of the first metal portion, and the first metal portion having a flat surface; wherein the first contact and the second contact are connected through a conduction structure of the plurality of the conduction structures.

In some embodiments, a method of forming a packaging conduction structure is provided and includes: providing a substrate, the substrate including a contact; connecting a composite metal ball to the contact, the composite metal ball including a first metal portion and a second metal portion, the first metal portion and the second metal portion being different metals, the second metal portion surrounding an entirety of the first metal portion; covering the substrate and the composite metal ball with an encapsulation layer; grinding or cutting the encapsulation layer and the composite metal ball in a direction parallel to the substrate, such that the first metal portion of the composite metal ball has a flat surface, and an exposed portion of the composite metal ball is exposed from the encapsulation layer; connecting a metal ball to the exposed portion of the composite metal ball; and applying heat such that the second metal portion of the composite metal ball and the metal ball fuse together.

These and other aspects of the present disclosure will become apparent from the following description of the embodiment taken in conjunction with the attached drawings and their captions, although variations and modifications therein may be affected without departing from the spirit and scope of the present disclosure.

### BRIEF DESCRIPTION OF THE DRAWINGS

The described embodiments may be better understood by reference to the following description and the accompanying drawings, in which:

FIG. 1 shows a method of forming a packaging conduction structure according to embodiments of the present disclosure;

FIG. 2A shows a packaging conduction structure based on a composite metal ball according to embodiments of the present disclosure, and is obtained from a metalloscope;

FIG. 2B shows a packaging conduction structure based on a solder ball, and is obtained from a metalloscope;

FIGS. 3A and 3B respectively show a single-sided encapsulated POP structure and a double-sided encapsulated POP structure according to embodiments of the present disclosure;

FIG. 4 shows a multi-layer POP structure according to embodiments of the present disclosure;

FIG. 5 shows a partially encapsulated POP structure according to embodiments of the present disclosure; and

FIG. 6 shows a double-sided partially encapsulated POP structure according to embodiments of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

The term “packaging unit” as used in the present disclosure refers to any component assembled in a packaging structure, including but not limited to: resistors, capacitors, inductors, transistors, diodes, chips, printed circuit board (PCB) boards, packaging modules, or any other components.

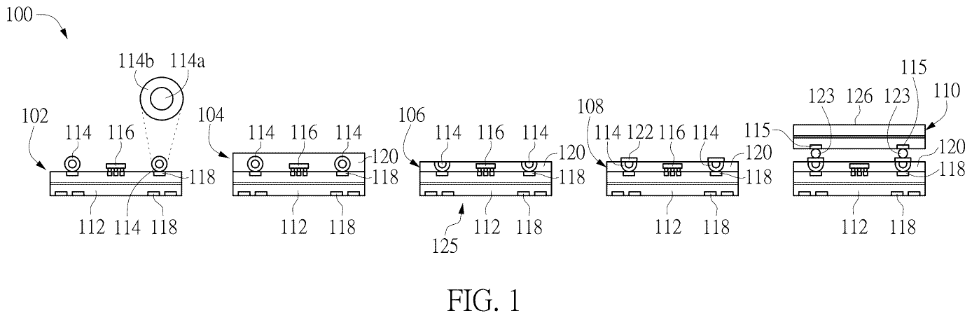

FIG. 1 illustrates a schematic diagram of a method 100 of forming a packaging conduction structure.

In step 102, a substrate 112 is provided, and the substrate 112 includes a contact 118. A chip 116 may be disposed on the substrate 112. In the step 102, a composite metal ball 114 is connected to the contact 118, and the composite metal ball 114 includes a first metal portion 114a and a second metal portion 114b. The first metal portion 114a and the second metal portion 114b are different metals, and the second metal portion 114b surrounds (or encloses) an entirety of the first metal portion 114a. In some embodiments, the first metal portion 114a includes copper, and the second metal portion 114b includes tin. In variant embodiments, other suitable metals can also be selected for the first metal portion 114a and the second metal portion 114b.

In step 104, an encapsulation layer 120 covers the substrate 112 and the composite metal ball 114. The encapsulation layer 120 can be any suitable epoxy molding compound (EMC), and the encapsulation layer 120 can prevent components from being affected by moisture and dust.

In step 106, the encapsulation layer 120 and the composite metal ball 114 are ground or cut in a direction parallel to the substrate 112, such that the first metal portion 114a of the composite metal ball 114 has an incomplete spherical shape, and the first metal portion 114a has a flat surface. The flat surface of the first metal portion 114a is coplanar with a surface of the encapsulation layer 120. The term “incomplete spherical shape” as used in the present disclosure refers to retaining a portion of a spherical shape, but due to missing a portion of the volume, the spherical shape is incomplete. For example, in the embodiment of FIG. 1, the “incomplete spherical shape” can be one half of a sphere. In other embodiments, the “incomplete spherical shape” can be a quarter of a sphere, three-quarters of a sphere, etc., but the present disclosure is not limited thereto. A portion of the composite metal ball 114 is exposed from the encapsulation layer 120. After the step 106, a packaging module 125 is formed, and the packaging structure can be assembled based on the packaging module 125, such as installing a component 126 on the packaging module 125 shown in FIG. 1, as described in steps 108 and 110 below.

In the step 108, optionally, solder 122 (e.g., solder paste) can be applied to the portion of the composite metal ball 114 exposed from the encapsulation layer 120, so as to assist in positioning a metal ball 123 thereon in the step 110 such that the metal ball 123 is connected to the portion of the composite metal ball 114 exposed from the encapsulation layer 120. In the step 110, the metal ball 123 is connected to a contact 115 of the component 126 for facilitating an installation of the component 126. After heating, the second metal portion 114b of the composite metal ball 114 and the metal ball 123 fuse together, forming a conduction structure. The second metal portion 114b and the metal ball 123 can include the same type of metal, such as tin. The conduction structure can electrically conduct between the contact 115 and the contact 118. The component 126 can be an active component (e.g., transistor), a passive component (e.g., resistor, capacitor, or inductor), a packaged chip, etc., but the present disclosure is not limited thereto.

In FIG. 1, since the packaging module 125 and the component 126 are assembled into a packaging structure, the packaging module 125 and the component 126 can both be regarded as a packaging unit.

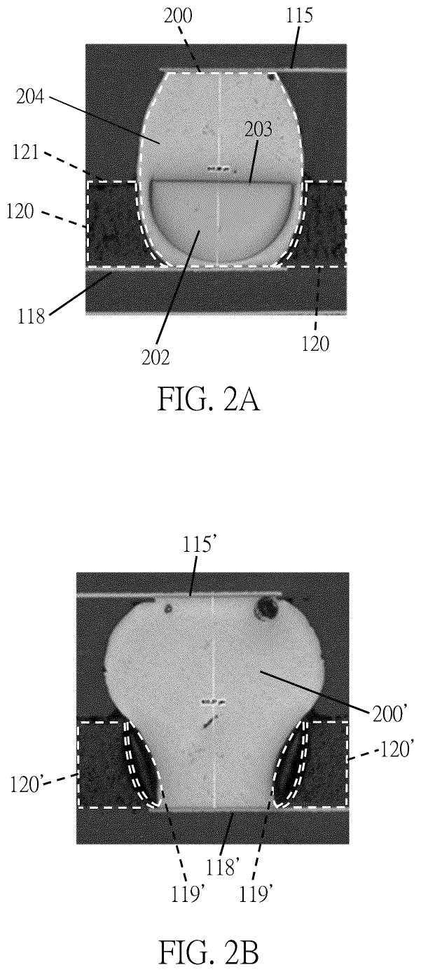

FIG. 2A is a cross-sectional view of a packaging conduction structure based on a composite metal ball, and is obtained from a metalloscope. FIG. 2B is a cross-sectional view of a packaging conduction structure based on a solder ball, and is obtained from a metalloscope. The comparison between FIG. 2A and FIG. 2B shows the differences between the packaging conduction structure based on the composite metal ball and the packaging conduction structure based on the solder ball. As previously described in step 110 of FIG. 1, the second metal portion 114b of the composite metal ball 114 and the metal ball 123 fuse together, and the form thereof can be seen with reference to the conduction structure 200 in FIG. 2A. As shown in FIG. 2A, the conduction structure 200 is connected between the contact 118 (which can be considered as the first contact) of the first packaging unit (e.g., the packaging module 125) and the contact 115 (which can be considered as the second contact) of the second packaging unit (e.g., the component 126). Signals can be transmitted through the conduction structure 200 along a vertical direction, shortening the distance and time of signal transmission. The conduction structure 200 includes a second metal portion 204 and a first metal portion 202. The second metal portion 204 surrounds an entirety of the first metal portion 202. In the embodiment of FIG. 2A, the conduction structure 200 is connected between the contact 115 and the contact 118 through the second metal portion 204. Corresponding to the result of the grinding or cutting operation on the encapsulation layer 120 and the composite metal ball 114 in the step 106 of FIG. 1, the first metal portion 202 of FIG. 2A has a flat surface 203, and the encapsulation layer 120 has a surface 121, and the flat surface 203 of the first metal portion 202 is coplanar with the surface 121 of the encapsulation layer 120. The first metal portion 202 has an incomplete spherical shape, the incomplete spherical shape in the embodiment of FIG. 2A is half of a sphere. As shown in FIG. 2A, the conduction structure 200 is surrounded by the encapsulation layer 120 below the surface 121. The first metal portion 202 and the second metal portion 204 of the conduction structure 200 are different metals, and the first metal portion 202 can prevent the second metal portion 204 from deforming during the heating process. For example, it can be seen from FIG. 2A that below the surface 121, the second metal portion 204 of the conduction structure 200 that is surrounded by the encapsulation layer 120 can fit well with the encapsulation layer 120, forming a stable structure. In contrast, FIG. 2B forms a conduction structure 200′ between the contact 115′ and the contact 118′ using only a solder ball. After heating, the solder ball is prone to deformation, and the portion surrounded by the encapsulation layer 120′ is especially prone to shrinkage, resulting in a gap 119′ between the conduction structure 200′ and the encapsulation layer 120′, making the structure less stable.

More specifically, the conduction structure 200 of the present disclosure has good stability in both vertical and horizontal directions due to at least the following factors:
(1) The second metal portion 204 is to an extent “bonded” to the contact and the contact 118; this bonding allows the conduction structure 200 to have shear resistance in the horizontal direction, enabling the second metal portion 204 to act as a stress buffer layer. Furthermore, increasing a bonding area between the second metal portion 204 and at least one of the contact 115 and the contact 118 can further enhance shear resistance. In contrast, some conduction structures are not bonded to the contact (e.g., using copper pillars or copper balls as the conduction structure; not shown in the drawings), but only rely on “contacting” for conduction with the contact, resulting in poor shear resistance in the horizontal direction. Although the conduction structure 200′ made of solder in FIG. 2B is also bonded to the contact 115′ and the contact 118′, the gap 119′ formed between the conduction structure 200′ and the encapsulation layer 120′ is disadvantageous to stress resistance in the vertical and horizontal directions, as further described in point (2) below.

(2) The first metal portion 202 can prevent the second metal portion 204 from deforming, enabling the second metal portion 204 surrounded (or enclosed) by the encapsulation layer 120 to fit well with the encapsulation layer 120. When the conduction structure 200 is subject to shear force in the horizontal direction, the encapsulation layer 120 can help to stabilize the conduction structure 200. When the conduction structure 200 is subject to normal force in the vertical direction, the encapsulation layer 120 (especially the portion engaging the second metal portion 204) can also help to distribute the force borne by the conduction structure 200. In contrast, the gap 119′ formed between the conduction structure 200′ and the encapsulation layer 120′ shown in FIG. 2B prevents the encapsulation layer 120′ from sharing the force borne by the conduction structure 200′ in the vertical direction or the horizontal direction, and further creates space for potential wobbling of the conduction structure 200′.

It can be seen from the above description that the conduction structure 200 of the present disclosure can avoid issues such as collapse, displacement, and instability of the overall packaging structure. In addition to structural stability, the conduction structure 200 of the present disclosure has other advantages. For example, the first metal portion 202 can be selected as a material with high thermal conductivity, such as copper, to improve the heat dissipation capability of the conduction structure 200. Therefore, the conduction structure 200 based on the composite metal ball has better heat dissipation compared to the conduction structure 200′based on the solder ball. Since heat is one of the many factors that cause component damage, good heat dissipation can also improve the reliability of components.

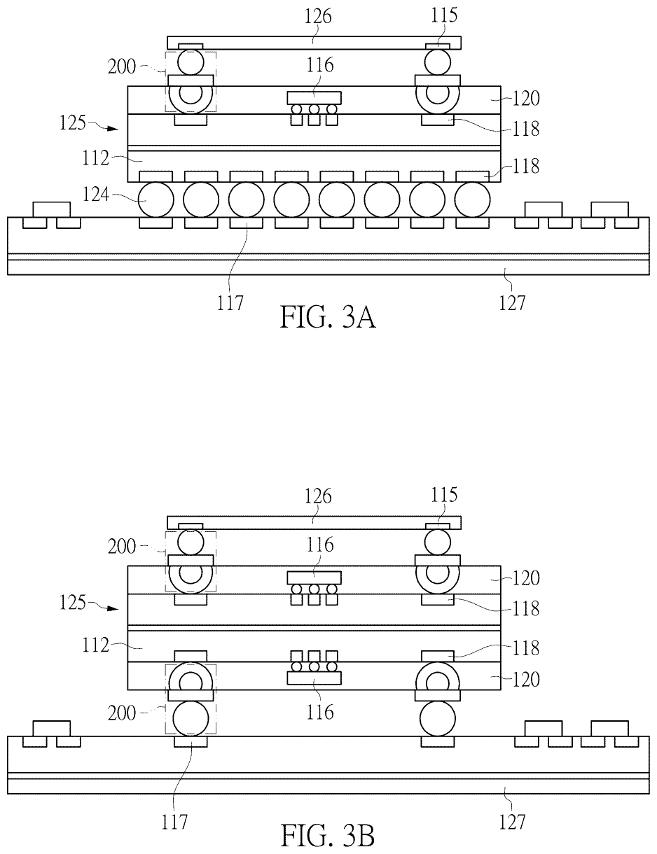

FIGS. 3A and 3B respectively illustrate a single-sided encapsulated POP structure and a double-sided encapsulated POP structure according to embodiments of the present disclosure.

Referring to FIG. 3A, the packaging module 125 includes a substrate 112, a chip 116 is disposed on the upper surface of the substrate 112, and the encapsulation layer 120 covers the chip 116 and the substrate 112. The packaging module 125 also includes a contact 118, and one or more contacts 118 can be connected to the chip 116. The component 126 is installed on the packaging module 125, and the contact 115 of the component 126 is connected to the contact 118 of the packaging module 125 through the conduction structure 200. The conduction structure 200 has been previously described with regard to FIG. 2A, so the following description is not repeatedly described herein for the sake of brevity. The lower surface of the packaging module 125 is connected to the mainboard 127 that can be a printed circuit board (PCB). A metal ball 124 (e.g., a solder ball) is disposed between the contact 118 of the packaging module 125 and the contact 117 of the mainboard 127. After heating (e.g., reflow), the metal ball 124 can form a conduction structure. Accordingly, signals are transmitted between the mainboard 127, the packaging module 125, and the component 126.

Referring to FIG. 3B, the packaging module 125 can be configured as the double-sided encapsulated structure. Compared to the embodiment in FIG. 3A, the packaging module 125 provided by the embodiment in FIG. 3B further encapsulates the lower surface of the substrate 112 with an encapsulation layer 120, and the connection between the contact 118 of the packaging module 125 and the contact 117 of the mainboard 127 is replaced by the conduction structure 200. Compared to the metal ball 124 in FIG. 3A, the conduction structure 200 has a composite metal structure (e.g., the first metal portion 202 and the second metal portion 204), which can further improve structural stability and heat dissipation. As previously described in FIG. 2A, the flat surface 203 of the first metal portion 202 of the conduction structure 200 is coplanar with the surface 121 of the encapsulation layer 120. When the conduction structure 200 is applied to the double-sided encapsulated structure of FIG. 3B, the flat surface 203 of the first metal portion 202 of each of the conduction structure 200 between the contact 115 and the contact 118 and the conduction structure 200 between the contact 118 and the contact 117 can be coplanar with their corresponding surface 121 of the encapsulation layer 120.

In FIGS. 3A and 3B, since the packaging module 125, the component 126, and the mainboard 127 are assembled into a packaging structure, and any one of the packaging module 125, the component 126, and the mainboard 127 can be regarded as a packaging unit.

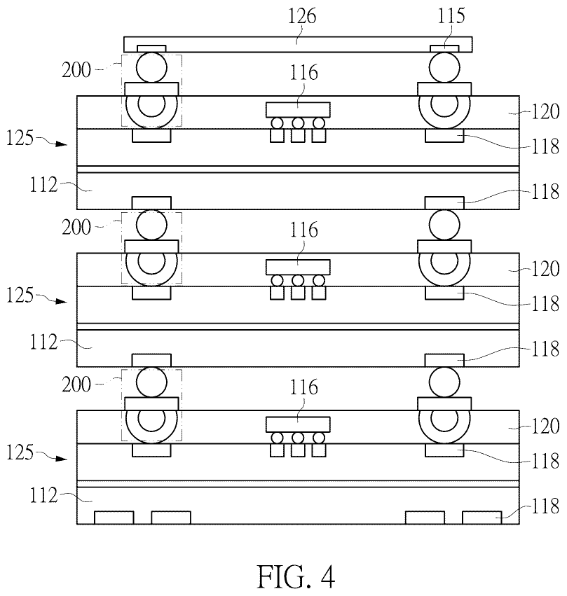

FIG. 4 illustrates a multi-layer POP structure according to embodiments of the present disclosure. This multi-layer POP structure stacks three packaging modules 125 on top of each other, and further installs a component 126 on a topmost one of the three packaging modules 125. Any two layers of the three packaging modules 125 and the component 126 adjacent to each other are connected by the conduction structure 200. A lowermost of the three packaging modules 125 can optionally further install a packaging module 125, component 126, or mainboard 127 (refer to the mainboard 127 in FIGS. 3A and 3B). The POP structure of the present disclosure can choose any number of packaging units (e.g., packaging module 125, component 126, or mainboard 127) for stacking, and connect them with the conduction structure 200 so that signals can be transmitted among them. As shown in FIG. 4, the packaging module 125 can include a chip 116, and the component 126 may also be a packaged chip, so the POP structure of the present disclosure can densely arrange chips therein to reduce size thereof and effectively utilize space. Since the POP structure of the present disclosure uses the conduction structure 200 for establishing a vertical connection therein, it can ensure the stability of the stacked structure during signal transmission.

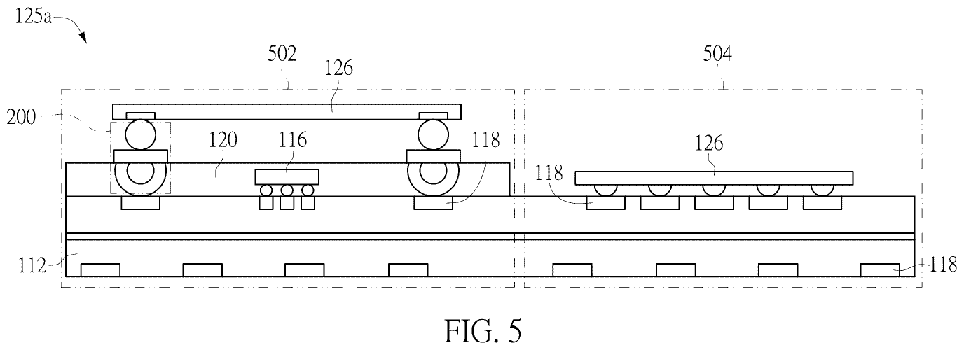

FIG. 5 illustrates a partially encapsulated POP structure according to embodiments of the present disclosure. As shown in FIG. 5, the packaging module 125a includes an encapsulation area 502 and a non-encapsulation area 504. The encapsulation layer 120 is arranged in the encapsulation area 502 and covers the substrate 112, and the encapsulation layer 120 does not exist (or is absent) in the non-encapsulation area 504. In the encapsulation area 502, the component 126 is connected to the contact 118 of the substrate 112 through the conduction structure 200. The component 126 can also be disposed in the non-encapsulation area 504. However, the component 126 in the non-encapsulation area 504 does not use the conduction structure 200 for connection, but uses other conduction means such as metal balls for connection. In actual applications, the areas to be encapsulated can be selected based on requirements such as stability, heat dissipation, etc.

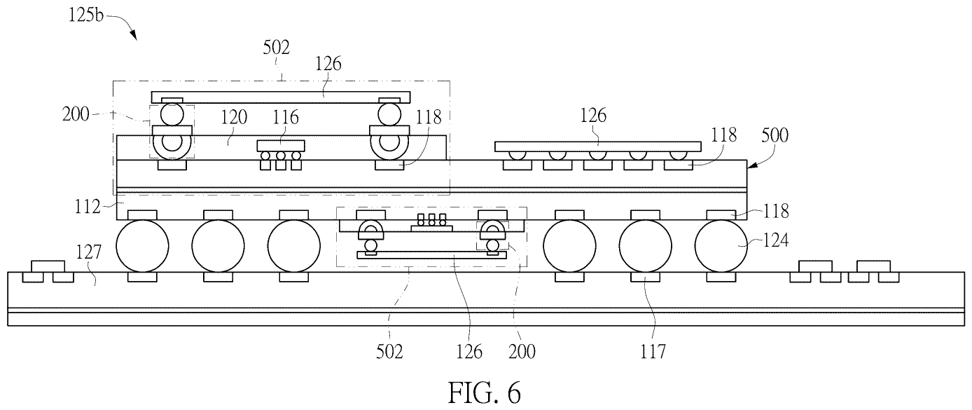

FIG. 6 illustrates a double-sided partially encapsulated POP structure according to embodiments of the present disclosure. As previously described in FIG. 5, the substrate 112 can optionally have only a portion to be encapsulated. FIG. 6 shows this partial encapsulation configuration is further applied to both the upper and lower surfaces of the substrate 112, thereby forming a packaging module 125b. As shown in FIG. 6, the encapsulation area 502 is distributed on a portion of the upper surface of the substrate 112, and on a portion of the lower surface of the substrate 112. The contact 118 in the encapsulation area 502 of the substrate 112 can be connected to the component 126 through the conduction structure 200, and the contact 118 in the non-encapsulation area of the substrate 112 can be connected to the component 126 or the mainboard 127 through the metal ball 124.

The foregoing description of the exemplary embodiments of the present disclosure has been presented only for the purposes of illustration and description and is not intended to be exhaustive or to limit the present disclosure. Many modifications and variations are possible in light of the above teaching.

The embodiments were chosen and described in order to explain the principles of the present disclosure and their applications. Alternative embodiments will become apparent to those skilled in the art to which the present disclosure pertains without departing from its spirit and scope.

What is claimed is:

1. A packaging conduction structure, comprising:
a first packaging unit comprising a first contact;
a second packaging unit comprising a second contact; and
a conduction structure comprising a first metal portion and a second metal portion, the first metal portion and the second metal portion being different metals, the second metal portion surrounding an entirety of the first metal portion, and the second metal portion being connected between the first contact and the second contact;
wherein the first metal portion has a flat surface.

2. The packaging conduction structure according to claim 1, wherein the first metal portion has an incomplete spherical shape.

3. The packaging conduction structure according to claim 1, wherein the first metal portion comprises copper, and the second metal portion comprises tin.

4. A package-on-package (POP) structure, comprising:
a first packaging unit comprising a first substrate and a first contact disposed on the first substrate;
a second packaging unit comprising a second contact; and
a plurality of conduction structures, each comprising a first metal portion and a second metal portion, the first metal portion and the second metal portion being different metals, the second metal portion surrounding an entirety of the first metal portion, and the first metal portion having a flat surface;
wherein the first contact and the second contact are connected through one of the plurality of the conduction structures.

5. The POP structure according to claim 4, wherein the first metal portion has an incomplete spherical shape.

6. The POP structure according to claim 4, wherein the first metal portion comprises copper, and the second metal portion comprises tin.

7. The POP structure according to claim 4, wherein the first packaging unit further comprises a first chip, and the first contact is connected to the first chip.

8. The POP structure according to claim 7, wherein the second packaging unit further comprises a second chip, and the second contact is connected to the second chip.

9. The POP structure according to claim 4, wherein the first packaging unit further comprises a first encapsulation layer, the first encapsulation layer covers at least a portion of the first substrate, and the following two are coplanar with each other: (1) a surface of the first encapsulation layer, and (2) the flat surface of the first metal portion of the conduction structure between the first contact and the second contact.

10. The POP structure according to claim 9, wherein the first packaging unit comprises an encapsulation region and a non-encapsulation region, the first encapsulation layer is arranged in the encapsulation region and covers the first substrate, and the first encapsulation layer is absent in the non-encapsulation region.

11. The POP structure according to claim 4, wherein the first substrate of the first packaging unit includes an upper surface and a lower surface, and a quantity of the first contact of the first packaging unit is at least two, and wherein the at least two first contacts are respectively disposed on the upper surface and the lower surface.

12. The POP structure according to claim 11, further comprising a third packaging unit, the third packaging unit comprising a third contact, wherein:
the second contact is connected to the first contact disposed on the upper surface through a conduction structure of the plurality of the conduction structures, and the third contact is connected to the first contact disposed on the lower surface through a conduction structure of the plurality of the conduction structures.

13. The POP structure according to claim 12, wherein the first packaging unit further comprises a first encapsulation layer and a second encapsulation layer, the first encapsulation layer covers at least a portion of the upper surface of the first substrate, and the second encapsulation layer covers at least a portion of the lower surface of the first substrate, wherein:
the following two are coplanar with each other: (1) a surface of the first encapsulation layer, and (2) the flat surface of the first metal portion of the conduction structure between the first contact and the second contact; and
the following two are coplanar with each other: (1) a surface of the second encapsulation layer, and (2) the flat surface of the first metal portion of the conduction structure between the first contact and the third contact.

14. A method of forming a packaging conduction structure, comprising:
providing a substrate, the substrate comprising a contact;
connecting a composite metal ball to the contact, the composite metal ball including a first metal portion and a second metal portion, the first metal portion and the second metal portion being different metals, the second metal portion surrounding an entirety of the first metal portion;
covering the substrate and the composite metal ball with an encapsulation layer;
grinding or cutting the encapsulation layer and the composite metal ball in a direction parallel to the substrate, such that the first metal portion of the composite metal ball has a flat surface, and an exposed portion of the composite metal ball is exposed from the encapsulation layer;
connecting a metal ball to the exposed portion of the composite metal ball; and
applying heat such that the second metal portion of the composite metal ball and the metal ball fuse together.

15. The method according to claim 14, wherein the first metal portion has an incomplete spherical shape.

16. The method according to claim 14, wherein the first metal portion comprises copper, the second metal portion comprises tin, and the metal ball comprises tin.

17. The method according to claim 14, wherein the second metal portion surrounds an entirety of the first metal portion after fusing together with the metal ball.

18. The method according to claim 14, wherein, after the grinding or the cutting of the encapsulation layer and the composite metal ball, the following two are coplanar with each other: (1) a surface of the encapsulation layer, and (2) the flat surface of the first metal portion.
